(19) United States
(12) Patent Application Publication
(10) Pub. No.: US 2011/0139224 A1
(43) Pub. Date: Jun. 16, 2011

(54) ORIENTED REINFORCEMENT FOR FRAMELESS SOLAR MODULES

(75) Inventor: Todd Krajewski, Mountain View, CA (US)

(73) Assignee: MIASOLE, Santa Clara, CA (US)

(21) Appl. No.: 12/639,346

(22) Filed: Dec. 16, 2009

(51) Int. Cl. H01L 31/048; H01L 31/0203

(52) U.S. Cl. 136/251; 438/66; 257/E31.117

(57) ABSTRACT

A frameless photovoltaic module retains the required load rating by incorporation of an oriented fibrous reinforcement (e.g., fibers, scrim or mesh) in the back side encapsulant, in the back sheet, or as a separate sheet between the encapsulant and the back sheet to increase the overall stiffness of the module. The reinforcement is compatible with the materials around it, in particular having good wet out, and may be freestanding or anchored to outer edges of the module, for example to the front glass, by means of an adhesive in order to further enhance the stiffness conferred to the module.

### BACKGROUND OF THE INVENTION

Photovoltaic cells are widely used for generation of electricity, with multiple photovoltaic cells interconnected in module assemblies. Such modules may in turn be arranged in arrays and integrated into building structures or otherwise assembled to convert solar energy into electricity by the photovoltaic effect. Individual modules are encapsulated to protect the module components from the environment. The modules are required to pass load testing to ensure that they can safely withstand snow loading and other environmental conditions. Typical thin film modules have either glass plates on both the front (light-incident) and back sides of the cells, or glass on the front and a weatherable flexible backsheet with a metal frame to allow them to pass the load ratings. Attempts to reduce module weight and cost through material alteration or replacement must comply with the load rating requirements.

### SUMMARY OF THE INVENTION

Module weight and production cost can be substantially reduced by replacing the back (non-light incident) sheet of glass in a frameless photovoltaic module with a lightweight, flexible material. Such a photovoltaic module retains the required load rating by incorporation of an oriented fibrous reinforcement (e.g., fibers, scrim or mesh) in the back side encapsulant, in the back layer, or as a separate sheet between the encapsulant and the back layer to increase the overall stiffness of the module. This fibrous reinforcement can be made of any material that confers sufficient stiffness and strength to the module to meet the required load rating for a photovoltaic module. Suitable fibrous materials have a longitudinal tensile strength greater than about 2000 MPa, or greater then about 3000 MPa, for example glass, carbon, metal (e.g., stainless steel or aluminum) or engineered polymer such as poly paraphenylene terephthalamide (e.g., Kevlar®), very high molecular weight linear low density polyethylene (e.g., Spectra®), or other such highly stiff and strong polymer fiber. The reinforcement should be compatible with the materials around it, in particular having good wet out, and may be freestanding or anchored at the outer edges of the module, for example to the front glass, by means of an adhesive in order to further enhance the stiffness conferred to the module. The invention finds particularly advantageous application in modules in which the conventional rigid back later has been replaced with a lightweight, flexible material, although its application is not so limited and the invention may beneficially applied in modules with rigid back layers (e.g., glass plates) as well.

One aspect of the invention relates to a frameless photovoltaic module having a light transmissive front layer, a back layer, and a plurality of interconnected photovoltaic cells disposed between the front layer and the back layer. An encapsulant is disposed between the plurality of solar cells and the back layer. A fibrous reinforcement is disposed within at least one of and/or between the back layer and the encapsulant. The module has substantially orthogonal length and width dimensions, and the fibrous reinforcement comprises fibers oriented substantially in the axis of at least one of the length and width dimensions.

Another aspect of the invention relates to a method of making a frameless photovoltaic module. The method involves assembling: a light transmissive front layer, a back layer; and a plurality of interconnected photovoltaic cells disposed between the front layer and the back layer. An encapsulant is disposed between the plurality of solar cells and the back layer. A fibrous reinforcement is disposed within at least one of and/or between the back layer and the encapsulant. The module has substantially orthogonal length and width dimensions, and the fibrous reinforcement comprises fibers oriented substantially in the axis of at least one of the length and width dimensions. The assembly is then laminated.

These and other aspects of the invention are described further below with reference to the figures.

### BRIEF DESCRIPTION OF THE DRAWINGS

FIG. 1A shows a cross-sectional view of certain components of a frameless photovoltaic module in accordance with the present invention.

FIG. 1B shows a plan view of certain components of a frameless photovoltaic module in accordance with the present invention.

FIG. 2 depicts a process flow showing certain operations in a process of forming a frameless photovoltaic module in accordance with the present invention.

### DETAILED DESCRIPTION

Reference will now be made in detail to specific embodiments of the invention. Examples of the specific embodiments are illustrated in the accompanying drawings. While the invention will be described in conjunction with these specific embodiments, it will be understood that it is not intended to limit the invention to such specific embodiments. On the contrary, it is intended to cover alternatives, modifications, and equivalents as may be included within the spirit and scope of the invention. In the following description, numerous specific details are set forth in order to provide a thorough understanding of the present invention. The present invention may be practiced without some or all of these specific details. In other instances, well known mechanical apparatuses and/or process operations have not been described in detail in order not to unnecessarily obscure the present invention.

Photovoltaic modules are required to meet load ratings specified by IEC 61646 and UL 1703, incorporated herein by reference for this purpose. In this regard, a module must be able to pass a 2400 MPa static load test for wind and 5400 MPa static loading test for snow/ice. The present invention is directed to frameless modules that are strengthened by incorporation of an oriented fibrous reinforcement (e.g., fibers, scrim or mesh) in the back side encapsulant, in the back layer, or as a separate sheet between the encapsulant and the back layer to increase the overall stiffness of the module. This fibrous reinforcement may be woven or non-woven can be made of any material that confers sufficient stiffness and strength to the module to meet the required load rating for a photovoltaic module. Suitable fibrous materials have a longitudinal tensile strength greater than about 2000 MPa, or greater then about 3000 MPa, for example glass, carbon, metal (e.g., stainless steel or aluminum) or engineered polymer such as poly paraphenylene terephthalamide (e.g., Kevlar®), very high molecular weight linear low density polyethylene (e.g., Spectra®), or other such highly stiff and strong polymer fiber. The reinforcement should be compatible with the materials around it, in particular having good wet out, and may be freestanding or anchored at the outer edges of the module, for example to the front glass, by means of an adhesive in order to further enhance the stiffness conferred to the module. The invention finds particularly advantageous application in modules in which the conventional rigid back later has been replaced with a lightweight, flexible material, although its application is not so limited and the invention may beneficially applied in modules with rigid back layers (e.g., glass plates) as well.

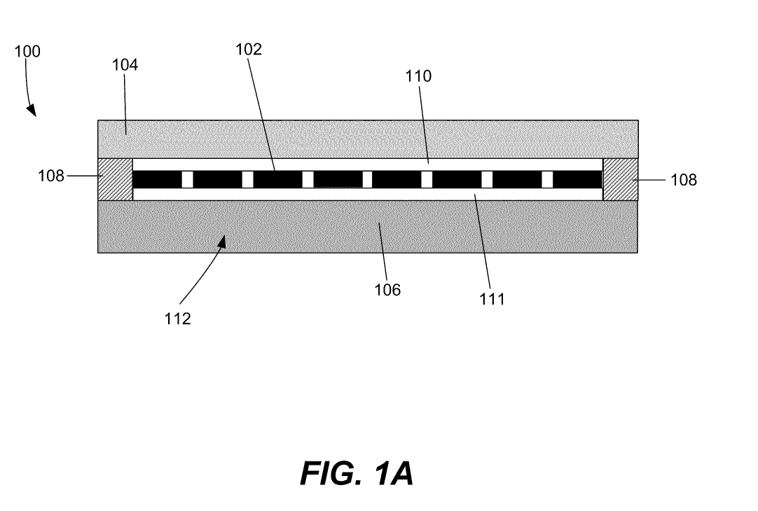

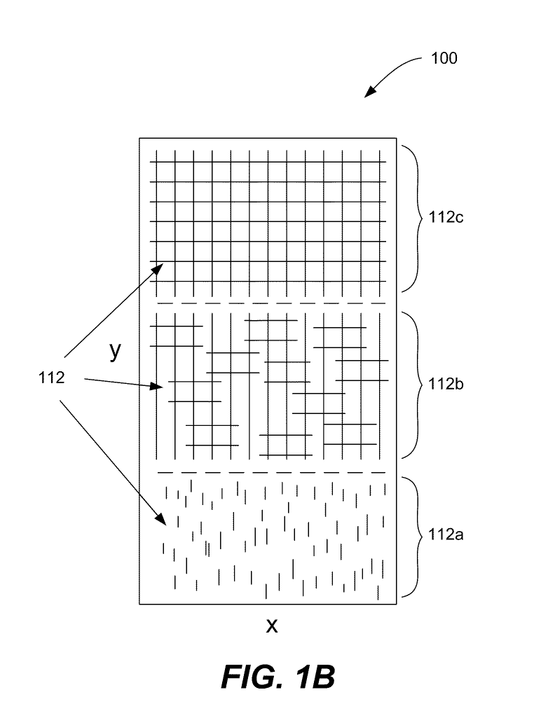

Embodiments of the present invention relate to reinforcement of frameless photovoltaic modules (also referred to as solar modules or solar panels). FIG. 1 shows a not-to-scale cross-sectional view of certain components of a frameless solar module 100 in accordance with one embodiment of the present invention. The module 100 includes interconnected solar cells 102 and front (light-incident) and back layers 104 and 106, respectively, for environmental protection and mechanical support. A light-transmissive thermoplastic polymer encapsulant 110 is also provided between the solar cells 102 and the front layer 104 to provide electrical insulation and further protection to the underlying solar cells by preventing direct contact between the solar cells and the generally rigid front layer 104. The same or a different encapsulant layer 111 may also be provided between the solar cells 102 and the back layer 106 for the same reasons. In certain modules, an additional edge material 108 surrounds the solar cells 102, and in this example, is embedded within encapsulating layers 110 and 111.

The front and back layers may be any suitable material that provides the environmental protection and mechanical support required for reliable module operation. In some typical embodiment, the front and back layers are rigid plates, light transmitting in the case of the front layer, such as glass, although other materials, such as polymers, multi-layer laminates and metals that meet the functional requirements may also be used. In other embodiments the typical rigid back layer (e.g., back glass plate) can be replaced with a much lighter weight flexible material, thereby reducing handling costs associated with the module.

The front, light-incident layer 104 should transmit visible and near visible wavelengths of the solar spectrum and be chemically and physically stable to anticipated environmental conditions, including solar radiation, temperature extremes, rain, snow, hail, dust, dirt and wind to provide protection for the module contents below. A glass plate comprising any suitable glass including conventional and float glass, tempered or annealed glass or combinations thereof or with other glasses is preferred in many embodiments. The total thickness of a suitable glass or multi-layer glass layer 104 may be in the range of about 2 mm to about 15 mm, optionally from about 2.5 mm to about 10 mm, for example about 3 mm or 4 mm. As noted above, it should be understood that in some embodiments, the front layer 104 may be made of a non-glass material that has the appropriate light transmission, stability and protective functional requirements. The front layer 104, whether glass or non-glass, transmits light in a spectral range from about 400 nm to about 1100 nm. The front layer 104 may not necessarily, and very often will not, transmit all incident light or all incident wavelengths in that spectral range equally. For example, a suitable front layer is a glass plate having greater than 50% transmission, or even greater than 80% or 90% transmission from about 400-1100 nm. In some embodiments, the front layer 104 may have surface treatments such as but not limited to filters, anti-reflective layers, surface roughness, protective layers, moisture barriers, or the like. Although not so limited, in particular embodiments the front layer 104 is a tempered glass plate about 3 mm thick.

The back layer 106 may be the same as or different than the front layer 104 and is also typically a glass plate as described above. However, since the back layer 106 does not have the same optical constraints as the front layer 104, it may also be composed of materials that are not optimized for light transmission, for example metals and/or polymers. And, while the present invention is applicable in more typical module configurations having both front and back glass plate layers, the invention finds particularly advantageous application in embodiments in which the back layer 104 is a lighter weight flexible material. In such embodiments, the back layer 106 may be a flexible yet weatherable laminate that protects the cells and other module components from moisture, UV exposure, extreme temperatures, etc. The back layer laminate may include a weatherable back sheet exposed to the exterior of the module. The back sheet should be resistant to environmental conditions expected to be experienced by the module (e.g., temperatures of about −40 to 90° C.), so that it is stable throughout the range of temperate climate temperatures and conditions so as to retain its properties to perform its protective function.

The back sheet may be composed of a fluoropolymer, including but not limited to polyvinyl fluoride (PVF) (e.g., Tedlar® film available from DuPont), polyvinylidene fluoride (PVDF), ethylene-tetrafluoroethylene (ETFE), fluorinated ethylene-propylene (FEP), perfluoroalkoxy (PFA) and polychlorotrifluoroethane (PCTFE). Other weatherable materials may be used in addition to or instead of a fluoropolymer, including silicone polyesters, chlorine-containing materials such as polyvinyl chloride (PVC), plastisols, polyethylene terephthalate (PET) and acrylics or combinations (laminated stacks) of the above. In certain embodiments, any material that meets UL 1703 requirements (incorporated by reference herein) can be used. In one example, the back layer includes PVF (e.g., Tedlar®). In certain examples, thickness range from about 2 to about 12 mils, although other thicknesses may be used as appropriate. A suitable flexible back layer laminate also includes a flexible moisture barrier sandwiched between an insulation sheet, for example a sheet of PET, and the weatherable back sheet. A suitable moisture barrier may be a metallic sheet, such as an aluminum foil. A suitable laminate back sheet in accordance with some embodiments of the invention is composed of a polyvinyl fluoride/Al foil/polyethylene terephthalate laminate (e.g., Tedlar®/Al foil/PET). Further description of suitable flexible back layers for photovoltaic cells that may be used in modules in accordance with the present invention is provided in US Published Application No. 2008/0289682 and co-pending commonly assigned U.S. application Ser. No. 12/464,721, each of which is incorporated by reference herein for this purpose.

The edge material 108 may be an organic or inorganic material that has a low inherent water vapor transmission rate (WVTR) (typically less than 1-2 g/m²/day) and, in certain embodiments may absorb moisture and/or prevent its incursion. In one example, a butyl-rubber containing moisture getter or desiccant is used.

The solar cells 102 may be any type of photovoltaic cell including crystalline and thin film cells such as, but not limited to, semiconductor-based solar cells including microcrystalline or amorphous silicon, cadmium telluride, copper indium gallium selenide or copper indium selenide, dye-sensitized solar cells, and organic polymer solar cells. In particular embodiments, the cells are copper indium gallium selenide cells. In other aspects of the invention, the cells can be deposited as thin films on the front, light-incident (e.g., glass) layer 104. Direct deposition of a solar cell on glass is described, for example, in US Patent Publication No. 2009/0272437, incorporated by reference herein for this purpose. In such an embodiment, element 110 of FIG. 1 would be absent and element 102 would be in contact with the front, light-incident layer 104.

The front side encapsulant 110 interposed between the plurality of solar cells 102 and the light transmissive front layer 104 provides electrical insulation and further protection to the underlying solar cells 102 by preventing direct contact between the solar cells and the generally rigid front layer 104. A suitable front encapsulant 110 is a light transmissive thermoset (undergoes irreversible curing) or thermoplastic (can be re-melted) polymer. The thickness of the encapsulant between the front layer and the solar cells may be from about 10 to 1000 microns, or about 25 to 700 microns, for example about 600 microns. Of course, in direct deposit embodiments of the invention, the front side encapsulant is absent. The front side encapsulant 110 may optionally include a CTE modifier, as described in commonly assigned, co-pending U.S. application Ser. No. 12/539,054 entitled CTE MODULATED ENCAPSULANTS FOR SOLAR MODULES, incorporated by reference herein for this purpose.

The back side encapsulant 111 interposed between the plurality of solar cells 102 and the back layer 106 provides electrical insulation and further protection to the underlying solar cells 102 by preventing direct contact between the solar cells and the back layer 106. A suitable back side encapsulant 111 is again a polymer encapsulant, generally a thermoset or thermoplastic polymer material, and may be the same or a different material from the front side encapsulant. The thickness of the back side encapsulant may also be from about 10 to 1000 microns, or about 25 to 700 microns, for example about 600 microns. There is no requirement of light transmissivity in the back side encapsulant.

NOM Suitable materials for both front and back side encapsulants form a durable, electrically insulating seal between the solar cells and the front or back layer. In many embodiments, encapsulants are polymers, in particular thermoplastic polymers. Examples of suitable front or back side encapsulants include non-olefin thermoplastic polymers or thermal polymer olefin (TPO). Particular examples include, but are not limited to, polyethylene, polypropylene, polybutylene, polyethylene terephthalate (PET), polybutylene terephthalate (PBT), polystyrene, polycarbonates, fluoropolymers, acrylics, ionomers, silicones and combinations thereof. In some embodiments the encapsulant is a polyethylene, in particular a linear, low density polyethylene, for example Z68, a linear, low density polyethylene available from Dai Nippon Printing (DNP). Other suitable encapsulants include various SURLYN® thermoplastic ionomeric resin grades (e.g., PV4000 or equivalent), and SENTRY GLASS® laminate interlayer available from DuPont, and GENIOMER® 145 thermoplastic silicone elastomer available from Wacker Chemie.

Referring in addition now to FIG. 1B, a module in accordance with the present invention also includes a fibrous reinforcement 112 in at least one of and/or between the back layer 106 and the back side encapsulant 111. The fibrous reinforcement 112 comprises fibers oriented substantially in the axis of at least one of the length and width dimensions of the module. For example, the module may have a width, x, and a length, y, where y>x, and the fibers of the fibrous reinforcement 112 may be oriented with the length axis of the module 100 such that the fibers are aligned substantially parallel to the length dimension of the module. The fibrous reinforcement may be non-woven fibers substantially all oriented in the same direction (as depicted in portion 112a of FIG. 1B), non-woven fibers cross-linked by fibers oriented in a different direction, for example substantially (but not necessarily) perpendicular (as depicted in portion 112b of FIG. 1B), or woven (e.g., a mesh or scrim) with the fibers substantially aligned with the at least one axis of the module, preferably but not necessarily the longer axis where there is one, or both axes (as depicted in portion 112c of FIG. 1B). It should be noted that FIG. 1B is a conceptual plan view consolidating the illustration of several embodiments of the invention in a single FIGURE for facility of presentation.

In some embodiments, the fibrous reinforcement is disposed between the back layer 106 and the back side encapsulant 111. In such cases, the fibrous reinforcement may be a discrete layer of woven or non-woven fibers between the back layer and the encapsulant, bonded to each of these other layers. This structure may be formed, for example, by disposing a sheet of mesh or scrim between the back layer 106 and the back side encapsulant prior to lamination, and then bonded to these other layers during lamination.

In other embodiments, the fibrous reinforcement is disposed within the encapsulant. In such embodiments, non-woven fibrous reinforcement may be mixed with the bulk encapsulant material and extruded or otherwise processed to form a reinforced encapsulant such that the fibers of the fibrous reinforcement align so that they can be oriented with an axis of the module when combined with other module elements during module fabrication. Cross-linking fibers could also be applied or embedded. Alternatively, a woven fibrous reinforcement (e.g., a mesh or scrim) could be applied to or embedded in the encapsulant as it is being extruded or otherwise processed into its sheet form.

In still other embodiments, the fibrous reinforcement is disposed within the back layer. In such embodiments, non-woven fibrous reinforcement may be mixed with the back sheet or insulation material of a back layer laminate material and extruded or otherwise processed to form a reinforced sheet such that the fibers of the fibrous reinforcement align so that they can be oriented with an axis of the module when combined with other module elements during module fabrication. Cross-linking fibers could also be applied or embedded. Alternatively, a woven fibrous reinforcement (e.g., a mesh or scrim) could be applied to or embedded in the insulation of back sheet material as it is being extruded or otherwise processed into its sheet form.

A module in accordance with the present invention may have the oriented fibrous reinforcement disposed in any one of or a combination of at least two of within the encapsulant, within the back layer and between the back layer and encapsulant, as described above.

The oriented fibrous reinforcement should be compatible with the materials around it, in particular having good wet out.

In various embodiments, the oriented fibrous reinforcement may be freestanding or it may be anchored at the outer edges of the module to provide additional strength and stiffness to the module. For example, a woven reinforcement may be bonded or otherwise connected at and/or near opposing edges of the front glass. Anchoring may be accomplished with an adhesive or clip element. In some embodiments a sheet of fibrous reinforcement may be tensioned to enhance the stiffness conferred to the module.

A reinforced module in accordance with the present invention can withstand the application of a 2400 MPa static load test for wind and 5400 MPa static loading test for snow/ice without damage. Suitable fibrous reinforcements in some embodiments comprise fibers having a longitudinal tensile strength of at least 2000 MPa, for example at least about 3000 MPa.

Suitable oriented fibrous reinforcements in accordance with the present invention may be composed of fibers of glass, high modulus polyimide, linear high molecular weight polyethylene, minerals and combinations of these. In specific embodiments, the fibers comprise glass. Suitable glass fibers have a diameter of at least 2 mils, for example 4 mils. Of course, other fiber compositions and sizes are possible as long as the stiffening of the module is enhanced and the load testing requirements are met.

Another aspect of the present invention involves the use of adhesion promoters to enhance bonding between the encapsulant, or other module component which it contacts or of which it forms a part, and the fibrous reinforcement. A number of materials are known to promote bonding between materials identified herein as suitable for encapsulants, for example, and fibrous reinforcements. Such materials can be incorporated into encapsulants, for example, such that a back side encapsulant comprises an adhesion promoter to enhance bonding to an oriented fibrous reinforcement. For example, siloxane may be incorporated into a thermoplastic polymer encapsulant to promote adhesion to a glass fibrous reinforcement, such as glass fibers, mesh or scrim. Additionally, or alternatively, a fibrous reinforcement may be treated to enhance bonding to an encapsulant or other module component. For example, a glass fibrous reinforcement may be silynized to enhance bonding to a thermoplastic polymer encapsulant.

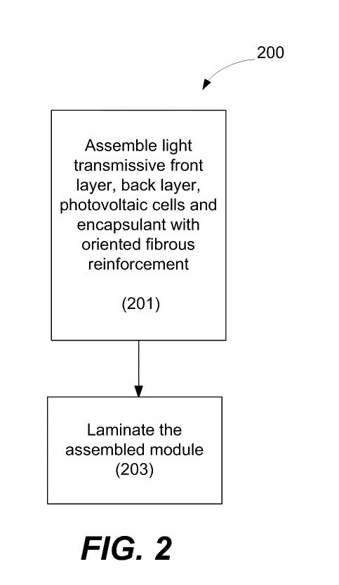

Another aspect of the invention is a method of making a frameless photovoltaic module. FIG. 2 depicts a process flow 200 showing certain operations in a process of forming a photovoltaic module in accordance with the present invention. A light transmissive front layer, a back layer, and a plurality of interconnected photovoltaic cells disposed between the light transmissive front layer and the back layer, and a back side encapsulant are assembled (201). An oriented fibrous reinforcement is disposed in any one of or a combination of at least two of within the encapsulant, within the back layer and between the back layer and encapsulant. The assembled module is then laminated (203).

### Example

Modeling was conducted in order to demonstrate the advantages provided by various aspects of this invention with regard to stiffening frameless photovoltaic modules so they can pass the high snow load test (5400 MPa). The data presented here are intended to better illustrate the invention as described herein and is non-limiting.

Calculations were made for a hypothetical module with and without an oriented fibrous reinforcement in accordance with the present invention subjected to a 5400 MPa static load. The calculations were based on a typical module without reinforcement (no fiber) and modules reinforced with unanchored oriented glass fiber scrim of the specified fiber thickness and properties in the module encapsulant:

Thickness of fibers: 2 mil and 4 mil
Young's modulus: 71 Gpa

### Poisson's Ratio: 0.22

### Longitudinal Tensile Strength: 3500 MPa

The results are tabulated below:

| | Max Stress |
|---|---|
| Case | (MPa) |
| No Fiber | 138.3 |
| 2 mil fiber | 123.5 |
| 4 mil fiber | 108.7 |

The modeling results show reduction of stress on the front glass at the 5400 MPa static load level, demonstrating that the oriented fibrous reinforcement enhances the stiffness of the module.

Although the foregoing invention has been described in some detail for purposes of clarity of understanding, it will be apparent that certain changes and modifications may be practiced within the scope of the invention. It should be noted that there are many alternative ways of implementing both the processes and apparatuses of the present invention. Accordingly, the present embodiments are to be considered as illustrative and not restrictive, and the invention is not to be limited to the details given herein.

What is claimed is:

1. A frameless photovoltaic module, comprising:
a light transmissive front layer;
a back layer;
a plurality of interconnected photovoltaic cells disposed between the front layer and the back layer;
an encapsulant disposed between the plurality of solar cells and the back layer; and
a fibrous reinforcement disposed within at least one of and/or between the back layer and the encapsulant;
wherein the module has substantially orthogonal length and width dimensions, and the fibrous reinforcement comprises fibers oriented substantially in the axis of at least one of the length and width dimensions.

2. The module of claim 1, wherein the back layer is flexible.

3. The module of claim 1, wherein the fibrous reinforcement is disposed between the back layer and the encapsulant.

4. The module of claim 2, wherein the fibrous reinforcement is comprised in a discrete layer between the back layer and the encapsulant.

5. The module of claim 1, wherein the fibrous reinforcement is disposed within the encapsulant.

6. The module of claim 1, wherein the fibrous reinforcement is disposed within the back layer.

7. The module of claim 1, wherein the oriented reinforcement is disposed in a combination of at least two of within the encapsulant, within the back layer and between the back layer and encapsulant.

8. The module of claim 1, wherein the fibrous reinforcement comprises fibers oriented in a length axis of the module.

9. The module of claim 8, wherein the fibrous reinforcement further comprises fibers cross-linking the fibers oriented in the length axis of the module.

10. The module of claim 9, wherein the fibrous reinforcement comprises woven fibers.

11. The module of claim 9, wherein the fibrous reinforcement comprises non-woven fibers.

12. The module of claim 1, wherein the fibers comprise a material selected from the group consisting of glass, high modulus polyimide, linear high molecular weight polyethylene, minerals and combinations thereof.

13. The module of claim 1, wherein the fibers comprise glass.

14. The module of claim 13, wherein the glass fibers have a diameter of at least 2 mils.

15. The module of claim 1, wherein the fibers have a longitudinal tensile strength of at least 2000 MPa.

16. The module of claim 1, wherein the fibers have a longitudinal tensile strength of at least about 3000 MPa.

17. The module of claim 1, wherein the module can withstand the application of a 5400 MPa static load to the front layer without damage.

18. The module of claim 1, wherein the fibrous reinforcement is anchored at opposing ends of the module.

19. The module of claim 5, wherein the encapsulant further comprises an adhesion promoter to enhance bonding between the encapsulant and the fibrous reinforcement.

20. The module of claim 19, wherein the fibrous reinforcement comprises glass fibers and the adhesion promoter is a siloxane.

21. The module of claim 5, wherein the fibrous reinforcement is treated to enhance bonding to the encapsulant.

22. The module of claim 21, wherein the fibrous reinforcement comprises silynized glass fibers.

23. The module of claim 1, wherein the front layer is a glass plate.

24. The module of claim 1, wherein the back layer comprises a laminate having a flexible moisture barrier sandwiched between an interior insulation sheet and an exterior weatherable back layer resistant to moisture, UV exposure and temperate climate temperature variations.

25. The module of claim 1, wherein the back layer comprises a polyvinyl fluoride/Al foil/polyethylene terephthalate laminate.

26. The module of claim 1, wherein the photovoltaic cells are CIGS cells.

27. The module of claim 1, wherein the encapsulant comprises a thermal polymer olefin (TPO).

28. The module of claim 1, wherein the encapsulant comprises a non-olefin thermoplastic polymer.

29. The module of claim 1, wherein the encapsulant is selected from the group consisting of polyethylene, polypropylene, polybutylene, polyethylene terephthalate (PET), polybutylene terephthalate (PBT), polystyrene, polycarbonates, fluoropolymers, acrylics, ionomers, silicones and combinations thereof.

30. The module of claim 1, wherein the encapsulant is a polyethylene.

31. The module of claim 1, wherein the encapsulant is a linear, low density polyethylene.

32. The module of claim 1, further comprising a second encapsulant is disposed between the plurality of solar cells and the front layer.

33. The module of claim 1, wherein the plurality of solar cells are deposited on a metallic substrate separate from the front and back layers.

34. The module of claim 1, wherein the plurality of solar cells are deposited as a thin film on the front layer.

35. A method of making a frameless photovoltaic module, the method comprising: assembling,
a light transmissive front layer;
a back layer;
a plurality of interconnected photovoltaic cells disposed between the front layer and the back layer;
an encapsulant disposed between the plurality of solar cells and the back layer; and
a fibrous reinforcement disposed within at least one of and/or between the back layer and the encapsulant;
wherein the module has substantially orthogonal length and width dimensions, and the fibrous reinforcement comprises fibers oriented substantially in the axis of at least one of the length and width dimensions; and
laminating the assembly.

36. The method of claim 35, wherein the back layer is a flexible back layer.
